(19) United States
(12) Patent Application Publication
(10) Pub. No.: US 2026/0123307 A1
(43) Pub. Date: Apr. 30, 2026

(54) METHODS OF IMPROVING EUV PATTERNING OF CONTACT HOLES AND VIAS BY ION IMPLANT AND DIRECTIONAL DEPOSITION

(71) Applicant: Applied Materials, Inc., Santa Clara, CA (US)

(72) Inventors: Charith Nanayakkara, Gloucester, MA (US); Swasti Bhatia, Gloucester, MA (US); John Hautala, Beverly, MA (US); Huixiong Dai, San Jose, CA (US); Chih-An Hsu, Milpitas, CA (US)

(73) Assignee: Applied Materials, Inc., Santa Clara, CA (US)

(21) Appl. No.: 18/929,005

(22) Filed: Oct. 28, 2024

(51) Int. Cl. H01L 21/3115; H01L 21/033

(52) U.S. Cl. CPC H10P 30/40; H10P 76/4085

(57) ABSTRACT

Systems and method for method of modifying an opening in a masking material layer to achieve desired critical dimensions can include forming a plurality of openings in the masking material layer, performing an ion implantation on the masking material layer to implant the masking material layer with a dopant material such that a material of the masking material layer is densified and the plurality of openings are enlarged, and directionally depositing a material layer on the masking material layer by directing a material beam at an angle relative to a top surface of the masking material layer that is selected such that the material beam is incident on sidewalls of the plurality of openings but substantially not on bottom surfaces of the plurality of openings.

### FIELD OF THE DISCLOSURE

Embodiments of the present disclosure relate generally to the field of semiconductor device fabrication, and more particularly to methods for modifying the size and shape of holes in hard masks and photoresists to achieve desired critical dimensions.

### BACKGROUND OF THE DISCLOSURE

In the integrated circuit (IC) industry, functional density (i.e., the number of interconnected devices per wafer area) has generally increased while geometry size (i.e., the smallest component that can be created using a fabrication process) has decreased. This scaling down process generally provides benefits by increasing production efficiency and lowering associated costs. However, such scaling down introduces challenges in maintaining process variations at acceptable levels within a wafer, wafer to wafer, and lot to lot.

For example, as process geometries continue to decrease, critical dimension (CD) of features of a wafer are becoming continually smaller, and variations in the CD across the wafer are increasing. The “CD” may refer to the smallest dimension of a feature along a given direction, such as a transistor gate width or a line width of another type of device feature. As CD variation increases, variation of performance characteristics of devices of the wafer also increases. For example, performance characteristics of transistors, such as saturation drain current and threshold voltage, fluctuate with the CD variation of transistor features, such as gate widths, spacer widths, other features of the transistors, or combinations thereof. The variation in performance characteristics of the transistors can lead to poor device performance and low yield.

In part because of the scaling down process described in the foregoing, inspection and measurement of surface features has become more important. Some features have especially important effects on final product function, performance, or reliability, and so their dimensions (e.g., CDs) are to be carefully controlled. Deviations of a feature's CD and cross-sectional shape, e.g., profile, from design dimensions may adversely affect the performance of the finished semiconductor device. As a result, the local CD uniformity (LCDU) across at least a region of the surface can be measured to characterize the performance of fabrication process control.

Therefore, there is an ongoing need to improve the local CD uniformity, CD uniformity across a given wafer, and CD consistency from wafer to wafer.

### SUMMARY

In accordance with this disclosure, systems and methods for modifying an opening in a masking material layer (e.g., a patterned photoresist layer or a patterned hard mask layer) to achieve desired critical dimensions in the mask produced thereby are provided. In one aspect, a method for modifying an opening in a masking material layer to achieve desired critical dimensions can include forming a plurality of openings in the masking material layer, performing an ion implantation on the mask to implant the masking material layer with a dopant material such that a material of the masking material layer is densified and the plurality of openings are enlarged, and directionally depositing a material layer on the masking material layer by directing a material beam at an angle relative to a top surface of the masking material layer. The angle at which the material layer is directionally deposited on the masking material layer can be selected such that the material beam is incident on sidewalls of the plurality of openings but substantially not on bottom surfaces of the plurality of openings.

In another aspect, a method of modifying an opening in a masking material layer to achieve desired critical dimensions can include forming a plurality of openings in the masking material layer, directing an ion beam at the masking material layer to implant the masking material layer with a dopant material selected from the group consisting of carbon, hydrogen, argon, neon, and xenon, wherein a material of the masking material layer is densified and the plurality of openings are enlarged, and directionally depositing a layer of carbon on the masking material layer by directing a deposited material beam at an angle relative to a top surface of the masking material layer that is selected such that the material beam is incident on sidewalls of the plurality of openings but substantially not on bottom surfaces of the plurality of openings.

Although some of the aspects of the subject matter disclosed herein have been stated hereinabove, and which are achieved in whole or in part by the presently disclosed subject matter, other aspects will become evident as the description proceeds when taken in connection with the accompanying drawings as best described hereinbelow.

### BRIEF DESCRIPTION OF THE DRAWINGS

By way of example, various embodiments of the disclosed techniques will now be described, with reference to the accompanying drawings, wherein:

FIGS. 1A and 1B are a top view and a cross-sectional view illustrating a semiconductor substrate and a masking material layer in accordance with the present disclosure;

FIGS. 2A and 2B are a top view and a cross-sectional view illustrating a first step of a method for improving patterning of contact holes in accordance with an embodiment of the present disclosure;

FIGS. 3A and 3B are a top view and a cross-sectional view illustrating a second step of a method for improving patterning of contact holes in accordance with an embodiment of the present disclosure;

FIG. 4 is a graph illustrating a change in a hole critical dimension resulting from the method for improving patterning of contact holes in accordance with an embodiment of the present disclosure;

FIGS. 5A-5D are cross-sectional views of a semiconductor substrate at various stages of the method for improving patterning of contact holes in accordance with an embodiment of the present disclosure;

### DETAILED DESCRIPTION

The present embodiments will now be described more fully hereinafter with reference to the accompanying drawings, wherein some embodiments are shown. The subject matter of the present disclosure may be embodied in many different forms and is not to be construed as limited to the embodiments set forth herein. These embodiments are provided so this disclosure will be thorough and complete, and will convey certain exemplary aspects of the subject matter to those skilled in the art. In the drawings, like numbers refer to like elements throughout.

Embodiments described herein generally relate to improved techniques for forming semiconductor structures including openings (e.g., vias or contact holes). In traditional approaches, etching of contact holes and vias with precise critical dimensions (CDs) and low variability is difficult with thin resists, such as extreme ultraviolet (EUV) resists less than 35 nm thick. Etching deep holes (e.g., greater than 50 nm) also requires good etch selectivity to the resist, which may be difficult in many cases. Printing thicker resists is often not desirable. Instead, adding film to the resist thickness without changing the CD and/or densifying the resist to increase the etch selectivity is advantageous.

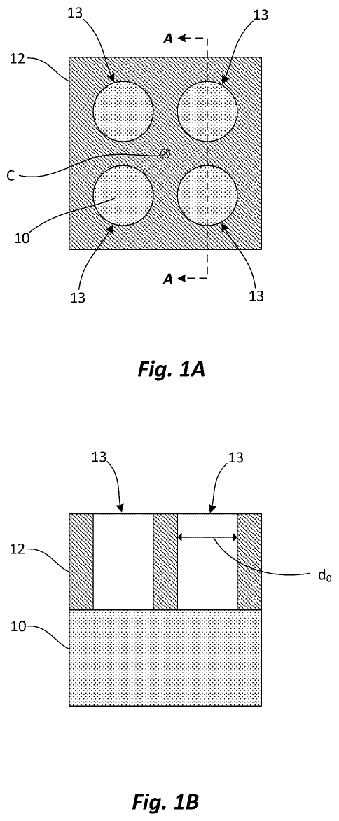

Referring to FIG. 1A, a top view illustrating a patterned hard mask or photoresist 12 (hereinafter generically referred to as “the masking material layer 12”) disposed atop a semiconductor substrate 10 is shown. FIG. 1B illustrates a cross-sectional view taken along lines A-A in FIG. 1A. The masking material layer 12 may have openings 13 formed therein to expose the underlying substrate 10 (i.e., when viewed from above). During a subsequent etching process, an ion beam formed of reactive ions may be directed at the masking material layer 12 from above such that the exposed portions of the underlying substrate 10 (i.e., the portions of the substrate 10 directly below the openings 13) are etched by the ion beam to create desired features (e.g., trenches) therein, while other portions of the substrate 10 are shielded from the ion beam by the masking material layer 12.

In various embodiments, the masking material layer 12 may be formed of silicon dioxide, silicon carbide, silicon nitride, or other mask layer materials that are known for use in deep ultraviolet (DUV) and/or EUV lithographic processes, such as chemically amplified resists (CAR) or metal oxide resists (MOR). The present disclosure is not limited in this regard, and the masking material layer 12 may alternatively be formed of other hard mask or photoresist materials known to those of ordinary skill in the art.

As shown in the illustrated embodiment, the masking material layer 12 may have round openings or other desired shapes that are formed using traditional manufacturing techniques, including, and not limited to, EUV lithography. When the masking material layer 12 is patterned, the openings 13 in the masking material layer 12 are ideally formed with a desired shape having desired dimensions, often referred to as “critical dimensions” (CDs), for transferring a desired etch pattern to a substrate. However, due to manufacturing constraints, it can be difficult or impossible to produce masks with openings having certain shapes with nanometer-scale dimensions with high reliability and precision, resulting in undesired CD variation. As used herein, the term “nanometer-scale” shall be defined herein to mean less than 1000 nanometers.

The embodiments of the present disclosure seek to address the challenges associated with producing openings having precise, nanometer-scale dimensions by using directional deposition and ion implantation processes to modify openings formed using traditional manufacturing processes. These two processes, both individually and taken together, can act to reduce the LCDU of the array of openings 13.

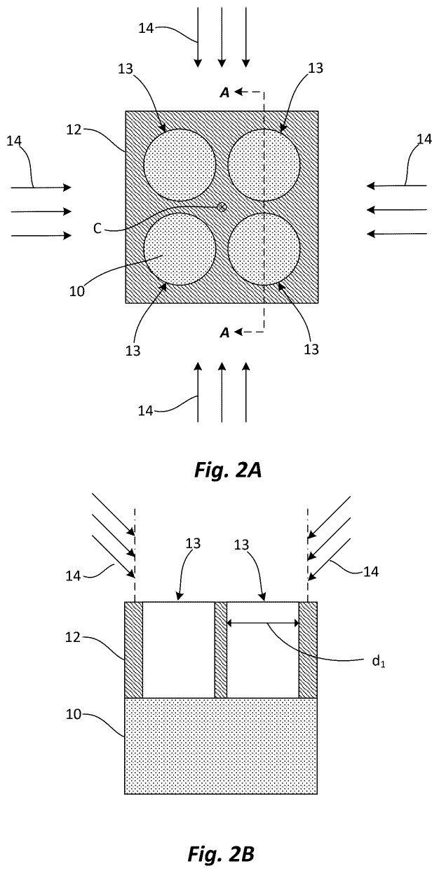

Referring to FIGS. 2A and 2B, an implantation process (a “pre-implant”) may be performed, wherein one or more ion beams 14 emitted from one or more ion sources (not shown) may be projected onto the masking material layer 12 to implant the masking material layer 12 with a dopant material. In various embodiments, the dopant material may be carbon, hydrogen, argon, neon, xenon, or another material selected to densify the masking material layer 12 that is applied using an ion energy that is less than or equal to about 5 kiloelectron volts (keV) and a dose in a range of between about 1×10¹³ ions/cm² and about 1×10¹⁶ ions/cm². The substrate 10 and/or the ion source(s) may be scanned, tilted, rotated, or otherwise repositioned during the ion implantation process to achieve substantially uniform implantation of the masking material layer 12. For example, the masking material layer 12 may be rotated about a central axis C that is substantially perpendicular to a top surface of the masking material layer 12 (e.g., in increments of 15 degrees, 45 degrees, 90 degrees, 180 degrees). The ion beams 14 may be directed at the masking material layer 12 in a direction substantially normal to the surface of the masking material layer 12 and/or the ion beams 14 may be directed at an angle in a range of about 0 degrees to about 80 degrees (e.g., about 45 degrees) relative to a line normal to the top surface of the substrate 10, although the present disclosure is not limited in this regard.

This ion implantation process may be configured to densify the material of the masking material layer 12, causing the portions of the masking material layer 12 between the openings 13 to shrink and causing the openings 13 themselves to be enlarged. In some embodiments, the densification is achieved by removing volatile components within the masking material layer 12, by modifying the structure of carbon-containing portions of the masking material layer 12, or through another process known to those having ordinary skill in the art.

In one example, the openings 13 may be enlarged from an initial diameter d₀ of about 26.5 nanometers shown in FIGS. 1A and 1B to a first modified diameter d₁ of about 28 nanometers shown in FIGS. 2A and 2B, an increase of about 5.6%, although the present disclosure is not limited in this regard. In addition, this densification of the masking material layer 12 can further act to reduce roughness in the masking material around the holes and/or vias, which can result in a reduction in the LCDU of the openings 13. In some embodiments, the ion energies applied can be selected to help control the penetration of ions into the masking material layer 12. It has been observed that the effects of ion implantation can be particularly beneficial where the masking material layer 12 is a photoresist.

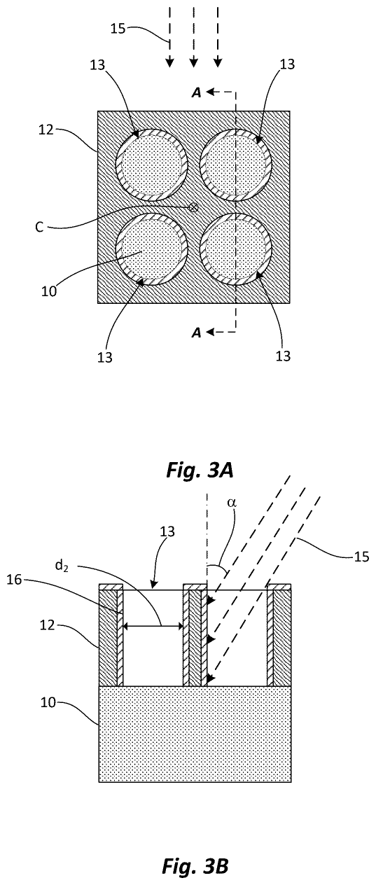

Referring to FIGS. 3A and 3B, concurrently with or subsequent to the ion implantation process, a directional deposition process may further be performed on the masking material layer 12, wherein a material beam 15 is projected onto the masking material layer 12 at an angle α with respect to a line normal to the surface of the masking material layer 12 to deposit a material layer 16 thereon. In some embodiments, the material beam 15 can comprise ions and/or radicals that are emitted from an ion source or are generated using a plasma-enhanced chemical vapor deposition (PECVD) process in which electrodes are positioned relative to the substrate 10 such that material is deposited at a desired angle. In various embodiments, the deposited material may be carbon, silicon nitride, amorphous silicon, or any of a variety of materials dissociated from a selected precursor (e.g., a combination of ions derived from a CH_{X} precursor in a PECVD process), although the present disclosure is not limited in this regard. In embodiments in which the masking material layer 12 comprises a photoresist film, the directional deposition process is controlled to be at or below 120° C., although other process limits could be used for different films.

In some embodiments, the angle α at which the material beam 15 is projected onto the masking material layer 12 is selected such that the material layer 16 is at least predominantly deposited on sidewalls of the openings 13 and little to no material is deposited on a bottom surface of the openings 13. In this way, this additional material deposition does not affect the etch of the exposed portion of the substrate 10 below the masking material layer 12. In this regard, in some embodiments, the angle α is selected based on the dimensions of the openings 13. For example, in configurations in which each of the openings 13 has an aspect ratio of its width with respect to its depth of about 0.6:1, an angle α of about 30° or greater can be selected such that the material beam 15 does not directly deposit material on the bottom surface of the openings 13. In other embodiments, in which the openings have a shallower configuration (e.g., each opening having an aspect ratio of its width to its depth of about 5:1), the angle α can be selected to be about 79° or greater such that material from the material beam 15 is predominantly deposited on the sidewalls of the openings 13. Thus, for many common configurations of openings 13, the angle α can be selected to have a value of between about 30° and about 80° with respect to a line normal to the top surface of the masking material layer 12. Those having ordinary skill in the art will recognize, however, that other values for the angle α can be selected to correspond to the dimensions of the openings 13.

In some embodiments, the material beam 15 can be emitted from a plurality of separate PECVD sources to ensure that material is deposited substantially uniformly about the sidewalls of each of the openings 13. Alternatively or in addition, the material beam 15 can be sequentially emitted from one or more PECVD source, wherein the substrate 10 and/or the PECVD source(s) may be repositioned for a plurality of deposition steps. For example, the masking material layer 12 may be rotated about the central axis C perpendicular to the surface of the masking material layer 12 (e.g., in increments of 15 degrees, 45 degrees, 90 degrees) after each of the plurality of deposition steps. Alternatively, the one or more PECVD sources can be rotated relative to the masking material layer 12 about the central axis C perpendicular to the surface of the masking material layer 12 (e.g., in increments of 15 degrees, 45 degrees, 90 degrees) after each of the plurality of deposition steps. In any configuration, the repositioning of the masking material layer 12 and/or the PECVD source(s) can ensure that material is deposited substantially uniformly on the sidewalls of the openings 13.

Alternatively, the directional deposition can be performed such that the material is deposited non-uniformly on the sidewalls of the openings 13. In some embodiments, for example, the material beam 15 can be sequentially or simultaneously emitted from two directions substantially opposing one another such that a majority of the material may be deposited on opposing lateral sides of the openings 13 onto which the material beam(s) 15 is projected. Thus, the widths of the openings 13 may be reduced to a desired width, thereby converting the openings 13 from holes to slots (“slot” is defined herein to mean an opening having a length greater than its width) as described in co-pending U.S. patent application Ser. No. 18/243,042, filed Sep. 6, 2023. Similarly in this regard, the directional deposition process can otherwise be controlled to modify the shape of the openings 13 to have a desired profile.

In any configuration, whereas the ion implantation process can result in the openings 13 being enlarged by the one or more ion beams 14, the directional deposition process can offset this enlargement by depositing the material layer 16 on the sidewalls of the openings 13 using the material beam 15. In some embodiments, the ion implantation process tends to enlarge the openings 13 at a rapid pace initially, but the rate of enlargement diminishes as the process is carried out over time. In contrast, the deposition process adds material to the surface on which the material beam 15 is incident at a rate that can be substantially linear over time. In this way, in some embodiments, the CD of the openings 13 can be controlled and the LCDU reduced by adjusting the process parameters for the combination of the ion implantation process and the directional deposition process. In addition, in some embodiments, the directional deposition process can further act to increase the height of the masking material layer 12.

In some embodiments, the ion implantation and the directional deposition processes can be performed sequentially, such as is suggested by the sequence illustrated in FIGS. 1A through 3B. Alternatively, in other embodiments, the ion implantation and the directional deposition processes can be performed concurrently. In some embodiments, the structure of the material layer 16 can be different when accompanied by ion bias. For example, in some embodiments, the concurrent application of these processes can reduce stress in the material layer 16 and/or produce a material layer 16 having a reduced density.

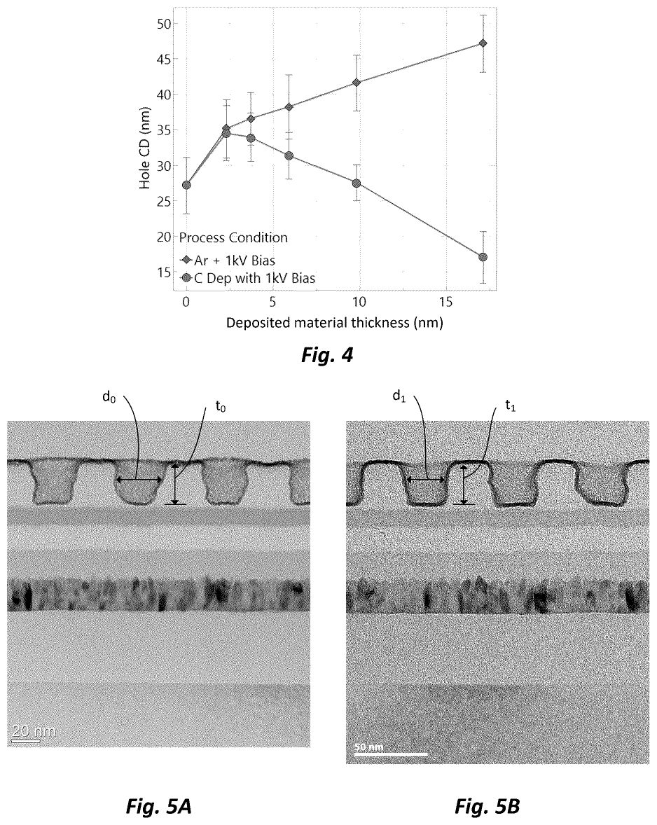

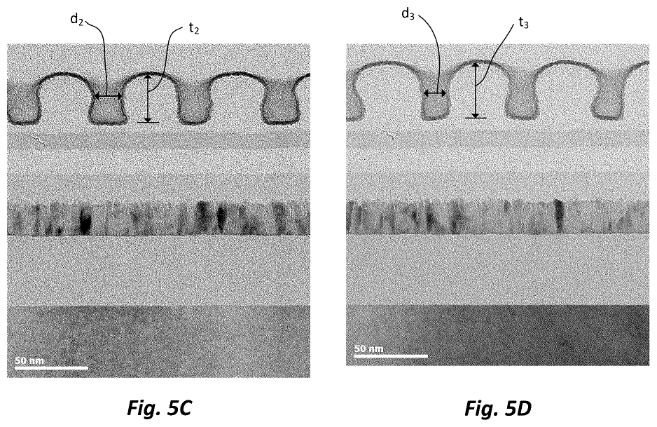

The relative effects of ion implantation and directional deposition on a plurality of openings 13 in a masking material layer 12 are illustrated with respect to a representative example embodiment shown in FIGS. 4-5D. As shown in FIG. 4, for example, an ion implantation process using argon ions having ion energies of about 1 keV is performed in combination with a directional deposition of carbon to a substrate on which a masking material layer 12 that is designed to serve as a patterned photoresist contains a plurality of openings 13 to adjust both the CD of each of the openings 13 and the LCDU of the plurality. Data representing the ion implantation alone is also plotted for comparison. As illustrated in FIG. 4, when the masking material layer 12 is fabricated (i.e., patterned via a lithographic process, corresponding to a subsequently deposited material thickness of 0 nm), each of a plurality of openings in an array having a pitch of 60 nm has a CD represented by an initial diameter d₀ having an average value of about 27.1 nm and a LCDU of about 3.95 nm when measured during an after-development inspection (ADI) (See, FIG. 5A). Application of an implantation process can rapidly increase the CD while the concurrent application of a directional deposition process can have only a marginal effect on reducing the CD in comparison, resulting in the CD increasing to a first modified diameter d₁ of about 32 nm as shown in FIG. 5B (corresponding to a material thickness of about 2.5 nm in FIG. 4).

As each process continues, however, the rate of enlargement produced by the ion implantation process diminishes and is overtaken by the rate of material added by the directional deposition process. In this way, continued application of the two processes can result in the CD being reduced again towards the original value. For example, in the illustrated embodiment, the combination of processes can be applied for a time selected to achieve a CD of each of the openings 13 having a second modified diameter d₂ having an average value of about 27.55 nm (corresponding to a deposited material thickness of about 10 nm in FIG. 4) as illustrated in FIG. 5C. Further application of both the ion implantation and directional deposition processes can result in further constriction of the openings 13, such as is shown in FIG. 5D in which the CD of each of the openings 13 is reduced to a third modified diameter d₃ having an average value of about 18.0 nm (corresponding to a deposited material thickness of about 17 nm in FIG. 4).

In addition to varying the CD of each of the openings 13, the combination of processes can affect the CD of different ones of the openings 13 to different extents, resulting in improved uniformity in the CDs among the plurality and a correspondingly reduced LCDU. As illustrated in the embodiment of FIG. 4, for example, although the average CD of the plurality of openings 13 is substantially similar prior to the application of the directional deposition process (i.e., d₀≈27.10 nm) and after a directional deposition onto the masking material layer 12 corresponding to an additional deposited material thicknesses of 10 nm (i.e., d₂≈27.55 nm), the LCDU of the plurality corresponding to the second modified diameter d₂ is about 2.55 nm, which is dramatically reduced from the initial LCDU of about 3.95.

Furthermore, in addition to decreasing the LCDU of an array of openings 13, the combination of ion implantation and directional material deposition can otherwise provide the ability to more precisely control the CD of the openings 13 by adjusting the parameters of each process. In some embodiments, for example, the openings 13 can be formed to have an average initial diameter do that is smaller than the desired final CD. Advantageously, in configurations in which the openings 13 are formed using EUV lithography, for example, a total EUV dose can thereby be reduced for the initial formation of the openings 13. The combination of ion implantation and directional deposition processes can then be used as discussed above to selectively control the diameter of openings 13 to have the desired CD. Specifically, the ion implantation process discussed above can be applied to densify the masking material layer 12 (e.g., to increase etch selectivity), where this process results in an enlargement of the CD of the openings 13 to a first modified d₁ that is equal to or greater than the desired CD. Directional deposition of ions and/or radicals can then be applied concurrently or subsequently to regulate the expansion of the openings 13 by the ion implantation process to achieve a second modified diameter d₂ that corresponds to the desired CD while also decreasing the LCDU as discussed above.

Alternatively or in addition, the more precise control over the CD of the openings 13 by the combination of ion implantation and directional deposition can also reduce the incidence of certain defects in the masking material layer 12. For example, for some openings 13 having small hole CDs (e.g., less than about 15 nm), a variability in the initial formation of the openings 13 (i.e., high LCDU among the openings 13) can result in one or more of the openings 13 not being fully formed through the masking material layer 12. Ion implantation can be applied in these situations to complete the formation of these “missing” holes within the masking material layer 12, while the directional deposition process can be applied to regulate the expansion of the openings 13 to achieve a desired CD and a reduced LCDU. Conversely, for some openings 13 having larger hole CDs (e.g., greater than about 20 nm), the high LCDU in the initial formation of the openings 13 can result in one or more adjacent openings 13 merging together. In these situations, the use of directional deposition can effectively rebuild the portions of the masking material layer 12 between the openings 13, thereby maintaining separation between the adjacent openings 13. Further, as used in combination with ion implantation as discussed above, such directional deposition can additionally act to reduce the LCDU of the array.

In addition, as shown in FIGS. 5A through 5D, the material deposition can further affect the total thickness of the masking material layer 12, increasing from an initial thickness to of about 30.5 nm (See, FIG. 5A), to a first modified thickness t₁ of about 32 nm corresponding to a total material deposition of about 2.5 nm (See, FIG. 5B), to a second modified thickness t₂ of about 38 nm corresponding to a total material deposition of about 10 nm (See, FIG. 5C), and up to a third modified thickness t₃ of about 46.2 nm corresponding to a total material deposition of about 17 nm (See, FIG. 5D). As a result, thinner masks can be initially disposed on the substrate 10, and the combination of the ion implantation and directional deposition processes can act to increase the total thickness of the masking material layer 12 to have a desired dimension.

Regardless of the particular parameters with which the ion implantation and directional deposition processes are applied in combination to achieve the desired critical dimensions, after the above-described implantation and deposition processes are performed, an etching process may be performed, wherein an ion beam formed of reactive plasma ions may be directed at the masking material layer 12 from above. The exposed portions of the underlying substrate 10 (i.e., the portions of the substrate 10 directly below the openings 13) may be etched by the ion beam to create corresponding openings therein, while other portions of the substrate 10 are shielded from the ion beam by the masking material layer 12. Example data indicates that improved LCDU is maintained when evaluated during an after-etch inspection (AEI). In one example implemented for contact holes having a pitch of 48 nm, a resist thickness of about 60 nm, an average CD of about 20.5 nm, and a LCDU of about 3.8 nm, the combination of ion implantation and directional deposition were applied to maintain an average CD of about 19.8 nm but to reduce the LCDU to about 2.6 nm. Similar results were found for a thinner resist having a pitch of 48 nm, a resist thickness of about 35 nm, an average CD of about 19.0 nm, and a LCDU of about 3.4 nm, where the combination of ion implantation and directional deposition resulted in an average CD of about 18.3 nm and a LCDU of 2.2 nm.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, while the present disclosure has been described herein in the context of a particular implementation in a particular environment for a particular purpose, those of ordinary skill in the art will recognize its usefulness is not limited thereto. Embodiments of the present disclosure may be beneficially implemented in any number of environments for any number of purposes. Accordingly, the claims set forth below shall be construed in view of the full breadth and spirit of the present disclosure as described herein.

1. A method of modifying an opening in a masking material layer provided on a substrate to achieve desired critical dimensions, the method comprising:
forming a plurality of openings in the masking material layer;
performing an ion implantation on the masking material layer to implant the masking material layer with a dopant material, wherein a material of the masking material layer is densified and the plurality of openings are enlarged; and
directionally depositing a material layer on the masking material layer by directing a material beam at a non-zero angle relative to a normal direction extending from a top surface of the masking material layer that is selected such that the material beam is incident on sidewalls of the plurality of openings but substantially not on bottom surfaces of the plurality of openings.

2. The method of claim 1, wherein forming the plurality of openings in the masking material layer comprises applying an extreme ultraviolet (EUV) lithography process to the masking material layer.

3. The method of claim 2, wherein applying the EUV lithography process comprises forming the plurality of openings with dimensions that are smaller than the desired critical dimensions.

4. The method of claim 1, wherein performing the ion implantation comprises using an ion energy that is less than or equal to about 5 kiloelectron volts (keV) and a dose in a range of between about 1×10¹³ ions/cm² and about 1×10¹⁶ ions/cm².

5. The method of claim 1, wherein the dopant material is selected from the group consisting of carbon, hydrogen, argon, neon, and xenon.

6. The method of claim 1, wherein performing the ion implantation comprises directing an ion beam at the masking material layer at an angle substantially normal to the top surface of the masking material layer.

7. The method of claim 1, wherein performing the ion implantation comprises directing an ion beam at the masking material layer at an angle in a range from about 0 degrees to about 80 degrees relative to the normal direction extending from the top surface of the masking material layer.

8. The method of claim 7, wherein the ion implantation comprises rotating the substrate relative to a source of the ion beam to a plurality of positions relative to a central axis that is substantially perpendicular to the top surface of the masking material layer.

9. The method of claim 1, wherein directionally depositing the material layer on the masking material layer comprises directing the material beam at an angle in a range from about 30 degrees to about 80 degrees relative to the normal direction extending from the top surface of the masking material layer.

10. The method of claim 1, wherein directionally depositing the material layer on the masking material layer comprises rotating a source of the material beam relative to the masking material layer to a plurality of positions relative to a central axis that is substantially perpendicular to the top surface of the masking material layer such that the material layer is deposited substantially uniformly on the sidewalls of the plurality of openings.

11. The method of claim 1, wherein directionally depositing a material layer comprises depositing a layer of carbon.

12. The method of claim 1, wherein the step of performing an ion implantation is performed prior to the step of directionally depositing a material layer.

13. The method of claim 1, wherein the steps of performing an ion implantation and directionally depositing a material layer are performed at the same time.

14. A method of modifying an opening in a masking material layer to achieve desired critical dimensions, the method comprising:
forming a plurality of openings in the masking material layer;
directing an ion beam at the masking material layer to implant the masking material layer with a dopant material selected from the group consisting of carbon, hydrogen, argon, neon, and xenon, wherein a material of the masking material layer is densified and the plurality of openings are enlarged; and
directionally depositing a layer of carbon on the masking material layer by directing a material beam at a non-zero angle relative to a normal direction extending from a top surface of the masking material layer that is selected such that the material beam is incident on sidewalls of the plurality of openings but substantially not on bottom surfaces of the plurality of openings.

15. The method of claim 14, wherein directionally depositing the layer of carbon on the masking material layer comprises directing the material beam at an angle in a range from about 30 degrees to about 80 degrees relative to the normal direction extending from the top surface of the masking material layer.

16. The method of claim 14, wherein directionally depositing the layer of carbon on the masking material layer comprises rotating a source of the material beam relative to the masking material layer to a plurality of positions relative to a central axis that is substantially perpendicular to the top surface of the masking material layer such that the layer of carbon is deposited substantially uniformly on the sidewalls of the plurality of openings.

17. The method of claim 14, wherein the step of directing an ion beam at the masking material layer is performed prior to the step of directionally depositing a layer of carbon.

18. The method of claim 14, wherein the steps of directing an ion beam at the masking material layer and directionally depositing a layer of carbon are performed at the same time.
